(19) United States
(12) Patent Application Publication
(10) Pub. No.: US 2018/0217463 A1
(43) Pub. Date: Aug. 2, 2018

(54) PIXEL STRUCTURE AND LIQUID CRYSTAL DISPLAY DEVICE

(71) Applicant: Shenzhen China Star Optoelectronics Technology Co., Ltd., Shenzhen, Guangdong (CN)

(72) Inventor: Jinbo Guo, Shenzhen, Guangdong (CN)

(73) Assignee: Shenzhen China Star Optoelectronics Technology Co., Ltd., Shenzhen, Guangdong (CN)

(21) Appl. No.: 15/500,183

(22) PCT Filed: Jan. 19, 2017
(86) PCT No.: PCT/CN2017/071740

§ 371 Date: Dec. 15, 2017

(30) Foreign Application Priority Data
Jan. 11, 2017 (CN) 201710017468.5

(51) Int. Cl. G02F 1/1362; G02F 1/1368; H01L 27/12

(52) U.S. Cl. CPC G02F 1/136286; G02F 1/1368; G02F 2201/123; H01L 27/124; G02F 1/136227

(57) ABSTRACT

Disclosed are a pixel structure and a liquid crystal display device. A data line and a common line are arranged in a same layer and are parallel to each other. A pixel area is located in a region surrounded by a scanning line and the data line. The pixel area includes a sub area which includes a first thin film transistor. Since the data line and the common line are arranged in a same layer, a through hole is no longer needed in connection of a source of the first thin film transistor and the common line. Hence, one through hole is omitted, thereby improving an aperture ratio of a pixel.

### CROSS-REFERENCE TO RELATED APPLICATIONS

This application claims the priority of Chinese patent application CN 201710017468.5, entitled “Pixel structure and liquid crystal display device” and filed on Jan. 11, 2017, the entirety of which is incorporated herein by reference.

### FIELD OF THE INVENTION

The present disclosure relates to the technical field of display, and in particular, to a pixel structure and a liquid crystal display device.

### BACKGROUND OF THE INVENTION

Vertical alignment (VA) thin film transistor liquid crystal display (TFT-LCD) devices have a serious color shift at a large viewing angle. The color shift is more obvious on large-size display panels. In order to solve the problem of color shift at a large viewing angle, low color shift pixel design is commonly used in designing of large-size display panels.

With reference to FIG. 1, reference numeral 1 denotes a scanning line, reference numeral 2 denotes a data line, and reference numeral 3 denotes a common line. In low color shift pixel design, a first metal layer is generally used as a common line 3, and therefore three through holes a, b, and c are necessary in a pixel structure. A thin film transistor T13 and a pixel electrode of a main area e are connected to each other via the through hole a; a thin film transistor T12 and a pixel electrode of a sub area d are connected to each other via the through hole b; and a thin film transistor T11 and the common line 3 are connected to each other via the through hole c. The three through holes take up a large space, but each single pixel has a small size, especially in design of panels of high resolutions. Therefore, arrangement of the three through holes has a great effect on an aperture ratio of a pixel, and is not conductive to pixel design of high aperture ratio and high transmittance.

### SUMMARY OF THE INVENTION

The present disclosure provides a pixel structure and a liquid crystal display device, so as to solve the technical problem in the prior art that too many through holes take up a large space, thereby affecting an aperture ratio of a pixel.

In one aspect, the present disclosure provides a pixel structure which comprises a scanning line, a data line, a common line, and a pixel area. The scanning line and the data line are arranged perpendicular to each other. The data line and the common line are arranged in a same layer and are parallel to each other. The pixel area is located in a region surrounded by the scanning line and the data line. The pixel area comprises a sub area which comprises a first thin film transistor. A gate of the first thin film transistor is connected to the scanning line, and a source of the first thin film transistor is connected to the common line.

Preferably, the sub area further comprises a second thin film transistor and a sub area pixel electrode. A gate of the second thin film transistor is connected to the scanning line, and a source thereof is connected to the data line. A drain of the second thin film transistor and a drain of the first thin film transistor both are connected to the sub area pixel electrode.

Preferably, the pixel structure further comprises a first through hole. The drain of the second thin film transistor is connected to the sub area pixel electrode via the first through hole.

Preferably, the pixel area further comprises a main area which comprises a third thin film transistor and a main area pixel electrode. A gate of the third thin film transistor is connected to the scanning line, a source thereof is connected to the data line, and a drain thereof is connected to the main area pixel electrode.

Preferably, the pixel structure further comprises a second through hole. The drain of the third thin film transistor is connected to the main area pixel electrode via the second through hole.

Preferably, the common line is located between the data line and the pixel area.

Preferably, the common line and the pixel area are partially overlapped.

In the other aspect, the present disclosure provides a liquid crystal display device which comprises a scan driving circuit, a data driving circuit, and the above-described pixel structure. A scanning line is connected to the scan driving circuit and is configured to transmit a scan signal generated by the scan driving circuit. A data line is connected to the data driving circuit and is configured to transmit a data signal generated by the data driving circuit.

In the pixel structure and the liquid crystal display device provided by the present disclosure, since the data line and the common line are arranged in a same layer, a through hole is no longer needed in connection of the source of the first thin film transistor and the common line. Hence, one through hole is omitted, thereby improving an aperture ratio of a pixel. For panels with relatively small size and high resolution, an aperture ratio can be improved in such a manner better, and transmittance can be further improved.

### BRIEF DESCRIPTION OF THE DRAWINGS

The accompanying drawings provide further understandings of the present disclosure and constitute one part of the description. The drawings are used for interpreting the present disclosure together with the embodiments, not for limiting the present disclosure. In the drawings:

FIG. 1 schematically shows a pixel structure in the prior art;

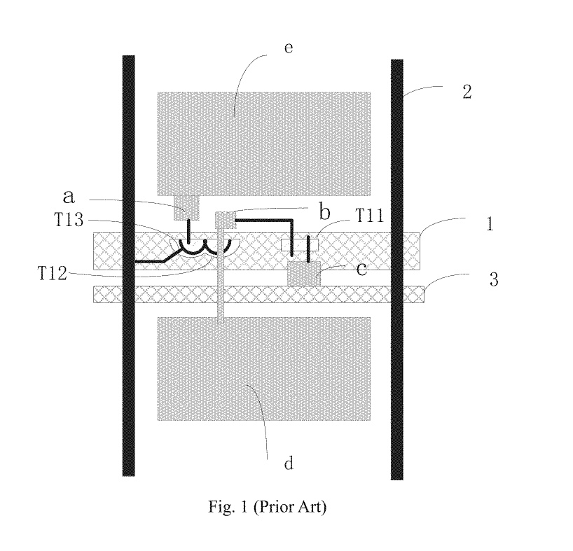

FIG. 2 schematically shows a pixel structure according to Embodiment 1 of the present disclosure; and

FIG. 3 schematically shows a circuit of the pixel structure according to Embodiment 1 of the present disclosure.

### DETAILED DESCRIPTION OF THE EMBODIMENTS

The present disclosure will be explained in details with reference to the embodiments and the accompanying drawings, whereby it can be fully understood how to solve the technical problem by the technical means according to the present disclosure and achieve the technical effects thereof, and thus the technical solution according to the present disclosure can be implemented. It should be noted that, as long as there is no conflict, all the technical features mentioned in all the embodiments can be combined together in any manner, and the technical solutions obtained in this manner all fall within the scope of the present disclosure.

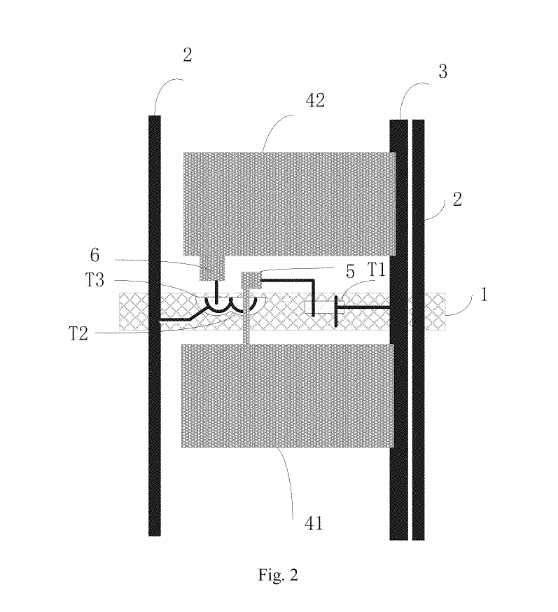

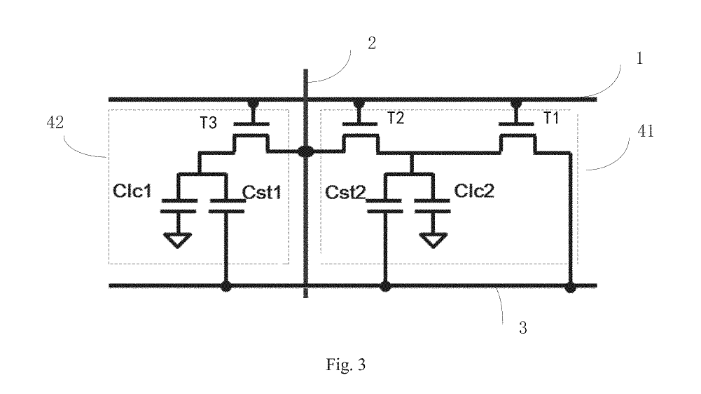

With reference to FIGS. 2 and 3, the present embodiment provides a pixel structure which comprises a scanning line 1, a data line 2, a common line 3, and a pixel area. The scanning line 1 and the data line 2 are arranged perpendicular to each other. The data line 2 and the common line 3 are arranged in a same layer and are parallel to each other. The pixel area is located in a region surrounded by the scanning line 1 and the data line 2. The pixel area comprises a sub area 41 which comprises a first thin film transistor T1. A gate of the first thin film transistor T1 is connected to the scanning line 1, and a source thereof is connected to the common line 3.

Since the data line 2 and the common line 3 are arranged in a same layer, a through hole is no longer needed in connection of the source of the first thin film transistor T1 and the common line 3. Hence, one through hole is omitted, thereby improving an aperture ratio of a pixel. For panels with relatively small size and high resolution, an aperture ratio can be improved in such a manner better, and transmittance can be further improved.

According to one specific embodiment of the present disclosure, the sub area 41 further comprises a second thin film transistor T2 and a sub area pixel electrode. A gate of the second thin film transistor T2 is connected to the scanning line 1, and a source thereof is connected to the data line 2. A drain of the second thin film transistor T2 and a drain of the first thin film transistor T1 both are connected to the sub area pixel electrode.

Further, the pixel structure further comprises a first through hole 5. The drain of the second thin film transistor T2 is connected to the sub area pixel electrode via the first through hole 5.

According to one specific embodiment of the present disclosure, the pixel area further comprises a main area 42 which comprises a third thin film transistor T3 and a main area pixel electrode. A gate of the third thin film transistor T3 is connected to the scanning line 1, a source thereof is connected to the data line 2, and a drain thereof is connected to the main area pixel electrode.

During charging process, the scanning line 1 turns on the first thin film transistor T1, the second thin film transistor T2, and the third thin film transistor T3 at the same time, and the main area 42 and the sub area 41 are charged. Meanwhile, the sub area 41 and the common line 3 are electrically connected to each other via the first thin film transistor T1. Thus, a portion of charges of the sub area 41 is leaked on the common line 3, and an electric potential of the sub area 41 is pulled down, resulting in a voltage difference between the main area 42 and the sub area 41. Different electric potentials cause alignment of liquid crystal molecules of the main area 42 and the sub area 41 to be different, thereby alleviating a color shift at a large viewing angle. A voltage of the first thin film transistor T1 determines a final electric potential and brightness of the sub area 41, and directly affects an effect of a low color shift. The voltage of the first thin film transistor T1 can be selected according to actual needs, and is not defined here.

Further, the pixel structure further comprises a second through hole 6. The drain of the third thin film transistor T3 is connected to the main area pixel electrode via the second through hole 6.

Further, the common line 3 is located between the data line 2 and the pixel area. Since there are potential fluctuations of the data line 2, it is liable to generate parasitic capacitance. Therefore, when the data line 2 and a pixel electrode (the main area pixel electrode or the sub area pixel electrode) are very close to each other, it is easy to cause vertical crosstalk. In order to solve this problem, a certain space is left between the data line 2 and a pixel electrode to avoid the vertical crosstalk.

In the pixel structure provided by the present disclosure, the common line 3 is located between the data line 2 and the pixel area. Since the common line 3 only has one electric potential, there is no vertical crosstalk caused when by the common line 3 and a pixel electrode are very close to each other. Furthermore, it is not necessary to leave a certain space between the common line 3 and data line 2. Preferably, the common line 3 is arranged at an original space between the data line 2 and the pixel electrode, and this would not increase a size of the pixel structure. Further, the common line and the pixel area are partially overlapped. The common line and the pixel area are not located in a same layer, and therefore the common line and the pixel area can be arranged partially overlapped. Such partially overlapped structure can save space, and can improve an aperture ratio of the pixel and reduce cost of a panel.

The present embodiment further provides a liquid crystal display device which comprises a scan driving circuit, a data driving circuit, and the above-described pixel structure. A scanning line is connected to the scan driving circuit and is configured to transmit a scan signal generated by the scan driving circuit. A data line is connected to the data driving circuit and is configured to transmit a data signal generated by the data driving circuit.

The above embodiments are described only for better understanding, rather than restricting, the present disclosure. Any person skilled in the art can make amendments to the implementing forms or details without departing from the spirit and scope of the present disclosure. The protection scope of the present disclosure shall be determined by the scope as defined in the claims.

1. A pixel structure, comprising a scanning line, a data line, a common line, and a pixel area, wherein the scanning line and the data line are arranged perpendicular to each other, the data line and the common line are arranged in a same layer and are parallel to each other, and the pixel area is located in an region surrounded by the scanning line and the data line,
wherein the pixel area comprises a sub area which comprises a first thin film transistor, a gate of which is connected to the scanning line, and a source of which is connected to the common line.

2. The pixel structure according to claim 1, wherein the sub area further comprises a second thin film transistor and a sub area pixel electrode,
wherein a gate of the second thin film transistor is connected to the scanning line; a source of the second thin film transistor is connected to the data line, and a drain of the second thin film transistor and a drain of the first thin film transistor both are connected to the sub area pixel electrode.

3. The pixel structure according to claim 2, further comprising a first through hole, wherein the drain of the second thin film transistor is connected to the sub area pixel electrode via the first through hole.

4. The pixel structure according to claim 1, wherein the pixel area further comprises a main area which comprises a third thin film transistor and a main area pixel electrode, wherein a gate of the third thin film transistor is connected to the scanning line, a source thereof is connected to the data line, and a drain thereof is connected to the main area pixel electrode.

5. The pixel structure according to claim 4, further comprising a second through hole, wherein the drain of the third thin film transistor is connected to the main area pixel electrode via the second through hole.

6. The pixel structure according to claim 1, wherein the common line and the pixel area are partially overlapped.

7. The pixel structure according to claim 2, wherein the common line and the pixel area are partially overlapped.

8. The pixel structure according to claim 4, wherein the common line and the pixel area are partially overlapped.

9. The pixel structure according to claim 5, wherein the common line and the pixel area are partially overlapped.

10. The pixel structure according to claim 1, wherein the common line is located between the data line and the pixel area.

11. The pixel structure according to claim 2, wherein the common line is located between the data line and the pixel area.

12. The pixel structure according to claim 4, wherein the common line is located between the data line and the pixel area.

13. The pixel structure according to claim 5, wherein the common line is located between the data line and the pixel area.

14. A liquid crystal display device, comprising a scan driving circuit, a data driving circuit, and a pixel structure, wherein:
a scanning line is connected to the scan driving circuit and is configured to transmit a scan signal generated by the scan driving circuit; and
a data line is connected to the data driving circuit and is configured to transmit a data signal generated by the data driving circuit,
wherein the pixel structure comprises a scanning line, a data line, a common line, and a pixel area,
wherein the scanning and the data line are arranged perpendicular to each other, the data line and the common line are arranged in a same layer and are parallel to each other, and the pixel area is located in an region surrounded by the scanning line and the data line; and
wherein the pixel area comprises a sub area which comprises a first thin film transistor, a gate of which is connected to the scanning line, and a source of which is connected to the common line.

15. The liquid crystal display device according to claim 14, wherein the sub area further comprises a second thin film transistor and a sub area pixel electrode,
wherein a gate of the second thin film transistor is connected to the scanning line; a source of the second thin film transistor is connected to the data line; and a drain of the second thin film transistor and a drain of the first thin film transistor both are connected to the sub area pixel electrode.

16. The liquid crystal display device according to claim 15, wherein the pixel area further comprises a first through hole, and the drain of the second thin film transistor is connected to the sub area pixel electrode via the first through hole.

17. The liquid crystal display device according to claim 14, wherein the pixel area further comprises a main area which comprises a third thin film transistor and a main area pixel electrode, wherein a gate of the third thin film transistor is connected to the scanning line, a source thereof is connected to the data line, and a drain thereof is connected to the main area pixel electrode.

18. The liquid crystal display device according to claim 17, wherein the pixel area further comprises a second through hole, and the drain of the third thin film transistor is connected to the main area pixel electrode via the second through hole.

19. The liquid crystal display device according to claim 14, wherein the common line and the pixel area are partially overlapped.

20. The liquid crystal display device according to claim 14, wherein the common line is located between the data line and the pixel area.
